(19) United States
(12) Patent Application Publication
(10) Pub. No.: US 2025/0374714 A1
(43) Pub. Date: Dec. 4, 2025

(54) Polarization Doped Current Spreading in Optoelectronic Device

(71) Applicant: Sensor Electronic Technology, Inc., Columbia, SC (US)

(72) Inventor: Joseph Dion, Columbia, SC (US)

(21) Appl. No.: 19/220,664

(22) Filed: May 28, 2025

Related U.S. Application Data
(60) Provisional application No. 63/653,003, filed on May 29, 2024.

(51) Int. Cl. H10H 20/816; H01S 5/22; H01S 5/30; H10F 77/124; H10F 77/14; H10H 20/812; H10H 20/821; H10H 20/825

(52) U.S. Cl. CPC H10H 20/816; H01S 5/22; H01S 5/3077; H10F 77/1246; H10F 77/146; H10F 77/147; H10H 20/812; H10H 20/821; H10H 20/825

(57) ABSTRACT

An optoelectronic device can include a first semiconductor layer with a mesa located on a portion of a surface thereof. The mesa can include an active region and a second semiconductor layer having a different conductivity than the first semiconductor layer. A contact can be located adjacent to the first semiconductor layer and the first semiconductor layer can be configured to distribute current flow away from a side of the mesa on which the contact is located. The first semiconductor layer can include a plurality of polarization doped channel layers.

### REFERENCE TO RELATED APPLICATIONS

The current application claims the benefit of U.S. Provisional Application No. 63/653,003, filed on 29 May 2024, which is hereby incorporated by reference.

### TECHNICAL FIELD

The disclosure relates generally to optoelectronic devices, and more particularly, to an optoelectronic device with improved current spreading.

### BACKGROUND ART

For a lateral current spreading light emitting device, the contact to the n-side of the device is made outside the mesa area. During operation, current travels laterally under the mesa before traveling vertically through the active region. This creates issues of current crowding, where the device current and emission is concentrated near the n-contact sides of the mesa. This non-uniform current density can limit the efficiency of the device and shorten its lifetime.

### SUMMARY OF THE INVENTION

Aspects of the invention provide an optoelectronic device can include a first semiconductor layer with a mesa located on a portion of a surface thereof. The mesa can include an active region and a second semiconductor layer having a different conductivity than the first semiconductor layer. A contact can be located adjacent to the first semiconductor layer and the first semiconductor layer can be configured to distribute current flow away from a side of the mesa on which the contact is located. The first semiconductor layer can include a plurality of polarization doped channel layers.

Further aspects of the invention provide an optoelectronic device that reduces current crowding near the n-contact side of a mesa. In embodiments, a current spreading layer with high conductivity is located below the n-side contact. In embodiments, the optoelectronic device is configured to emit ultraviolet light. In embodiments, the optoelectronic device is formed of group III-V materials. In more particular embodiments, the group III-V materials are group III nitride materials.

A first aspect of the invention provides an optoelectronic device comprising: a first semiconductor layer having a first conductivity type; a mesa located on a first portion of a surface of the first semiconductor layer, the mesa including: an active region located on the first semiconductor layer, wherein the active regions is configured to emit or sense radiation having a peak wavelength during operation of the optoelectronic device; and a second semiconductor layer having a second conductivity type located on the active region; and a contact located adjacent to the first semiconductor layer on a first side of the mesa, wherein the first semiconductor layer is configured to distribute current flow away from the first side of the mesa during operation of the optoelectronic device.

A second aspect of the invention provides an optoelectronic device comprising: a first semiconductor layer having an n-type conductivity; a mesa located on a first portion of a surface of the first semiconductor layer, the mesa including: an active region located on the first semiconductor layer, wherein the active region is configured to emit ultraviolet radiation during operation of the optoelectronic device; and a second semiconductor layer having a p-type conductivity located on the active region; and an n-type contact located adjacent to the first semiconductor layer on a first side of the mesa, wherein the first semiconductor layer includes a plurality of polarization doped channel layers.

A third aspect of the invention provides an optoelectronic device comprising: a group III-nitride based heterostructure including: a first semiconductor layer having an n-type conductivity; and a mesa located on a first portion of a surface of the first semiconductor layer, the mesa including: an active region located on the first semiconductor layer, wherein the active region is configured to emit ultraviolet radiation during operation of the optoelectronic device; and a second semiconductor layer having a p-type conductivity located on the active region; and an n-type contact located on a second portion of the surface of the first semiconductor layer adjacent to the mesa, wherein the first semiconductor layer includes a plurality of polarization doped channel layers.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1 shows a schematic structure of an illustrative optoelectronic device according to embodiments.

FIGS. 2A and 2B show illustrative current flow through a current spreading layer during operation of a corresponding optoelectronic device according to embodiments.

FIGS. 3A and 3B show illustrative n-type current spreading layers according to embodiments.

FIG. 4 shows an illustrative flow diagram for fabricating a circuit according to an embodiment.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide an optoelectronic device that reduces current crowding near the n-contact side of a mesa. In embodiments, a current spreading layer with high conductivity is located below the n-side contact. In embodiments, the optoelectronic device is configured to emit ultraviolet light. In embodiments, the optoelectronic device is formed of group III-V materials. In more particular embodiments, the group III-V materials are group III nitride materials.

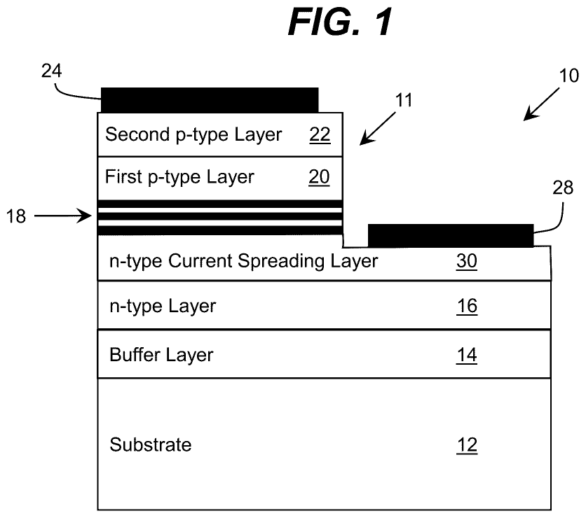

Turning to the drawings, FIG. 1 shows a schematic structure of an illustrative optoelectronic device 10 according to embodiments. In a more particular embodiment, the optoelectronic device 10 is configured to operate as an emitting device, such as a light emitting diode (LED) or a laser diode (LD). In either case, during operation of the optoelectronic device 10, application of a bias comparable to the band gap results in the emission of electromagnetic radiation from an active region 18 of the optoelectronic device 10. Alternatively, the optoelectronic device 10 can operate as a sensing device, such as a photodiode. In this case, electromagnetic radiation impinging the active region 18 can result in a bias corresponding to an irradiance of the electromagnetic radiation.

The electromagnetic radiation emitted (or sensed) by the optoelectronic device 10 can have a peak wavelength within any range of wavelengths, including visible light, ultraviolet radiation, deep ultraviolet radiation, infrared light, and/or the like. In embodiments, the device 10 is configured to emit (or sense) radiation having a dominant wavelength within the ultraviolet range of wavelengths. In more specific embodiments, the dominant wavelength is within a range of wavelengths between approximately 210 and approximately 360 nanometers.

The optoelectronic device 10 includes a heterostructure comprising a substrate 12, a buffer layer 14 adjacent to the substrate 12, an n-type layer 16 (e.g., a cladding layer, electron supply layer, contact layer, and/or the like) adjacent to the buffer layer 14, and an n-type current spreading layer 30 described herein. The heterostructure includes a mesa 11, which includes an active region 18 having an n-type side adjacent to the n-type current spreading layer 30, a first p-type layer 20 (e.g., an electron blocking layer, a cladding layer, hole supply layer, and/or the like) adjacent to a p-type side of the active region 18 and a second p-type layer 22 (e.g., a cladding layer, hole supply layer, contact layer, and/or the like) adjacent to the first p-type layer 20.

It is understood that the heterostructure is only illustrative of various heterostructure configurations that can be utilized to form an optoelectronic device 10 described herein. To this extent, embodiments of optoelectronic devices 10 can include heterostructures with additional layers, without one or more layers (e.g., the substrate 12, the buffer layer 14, a second p-type layer 22, and/or the like), and/or with different layer configurations. Similarly, it is understood that the mesa 11 shown for the heterostructure is only illustrative of various mesa configurations that can be used to form an optoelectronic device 10 described herein.

In a more particular illustrative embodiment, the optoelectronic device 10 is a group III-V materials based device, in which some or all of the various layers are formed of elements selected from the group III-V materials system. In a still more particular illustrative embodiment, the various layers of the optoelectronic device 10 are formed of group III nitride based materials. Group III nitride materials comprise one or more group III elements (e.g., boron (B), aluminum (Al), gallium (Ga), and indium (In)) and nitrogen (N), such that B_{W}Al_{X}Ga_{V}In_{Z}N, where 0≤W, X, Y, Z≤1, and W+X+Y+Z=1. Illustrative group III nitride materials include binary, ternary and quaternary alloys such as, AlN, GaN, InN, BN, AlGaN, AlInN, AIBN, AlGaInN, AlGaBN, AlInBN, and AlGaInBN with any molar fraction of group III elements.

An illustrative embodiment of a group III nitride based optoelectronic device 10 includes an active region 18 (e.g., a series of alternating quantum wells and barriers) composed of In_{y}AlₓGa_{1-x-y}N, Ga_{z}In_{y}AlₓB_{1-x-y-z}N, an AlₓGa₁₋ₓN semiconductor alloy, or the like. Similarly, the n-type layer 16, the n-type current spreading layer 30, the first p-type layer 20, and the second p-type layer 22 can be composed of an In_{y}AlₓGa_{1-x-y}N alloy, a Ga_{z}In_{y}AlₓB_{1-x-y-z}N alloy, or the like. The group III molar fractions given by x, y, and z can vary between the various layers 16, 18, 20, 22, and 30.

When the optoelectronic device 10 is configured to be operated in a flip chip configuration, the substrate 12 and buffer layer 14 can be transparent to the target electromagnetic radiation. To this extent, an embodiment of the substrate 12 is formed of sapphire, and the buffer layer 14 can be composed of AlN, an AlGaN/AlN superlattice, and/or the like. However, it is understood that the substrate 12 can be formed of any suitable material including, for example, silicon carbide (SiC), silicon (Si), bulk GaN, bulk AlN, bulk or a film of AlGaN, bulk or a film of BN, AlON, LiGaO₂, LiAlO₂, aluminum oxinitride (AlOₓN_{y}), MgAl₂O₄, GaAs, Ge, or another suitable material. Furthermore, a surface of the substrate 12 can be substantially flat or patterned using any solution. In embodiments, the substrate 12 and/or buffer layer 14 can be at least partially removed from the device 10, e.g., to improve emission from the device.

The optoelectronic device 10 can further include a p-type contact 24, which can form an ohmic contact to the second p-type layer 22. Similarly, the optoelectronic device 10 can include an n-type contact 28, which can form an ohmic contact to the n-type current spreading layer 30. While not shown, additional components, such as one or more electrodes (e.g., formed of one or more highly conductive metals), one or more dielectric layers, etc., can be included to incorporate the optoelectronic device 10 in a circuit.

In an embodiment, the p-type contact 24 and/or the n-type contact 28 comprises several conductive and reflective metal layers. In an embodiment, the second p-type layer 22 and/or the p-type contact 24 can be transparent to the electromagnetic radiation generated by the active region 18. For example, the second p-type layer 22 and/or the p-type contact 24 can comprise a short period superlattice lattice structure, such as an at least partially transparent magnesium (Mg)-doped AlGaN/AlGaN short period superlattice structure (SPSL). Furthermore, the p-type contact 24 and/or the n-type contact 28 can be reflective of the electromagnetic radiation generated by the active region 18. In another embodiment, the n-type layer 16 and/or the n-type contact 28 can be formed of a short period superlattice, such as an AlGaN SPSL, which is transparent to the electromagnetic radiation generated by the active region 18.

As discussed herein, embodiments of the optoelectronic device 10 include an n-type current spreading layer 30. As illustrated, the n-type current spreading layer 30 can be in direct contact with the n-type contact 28 and the n-type side of the active region 18. While both an n-type layer 16 and an n-type current spreading layer 30 are shown, it is understood that embodiments of the optoelectronic device 10 can be implemented without an n-type layer 16.

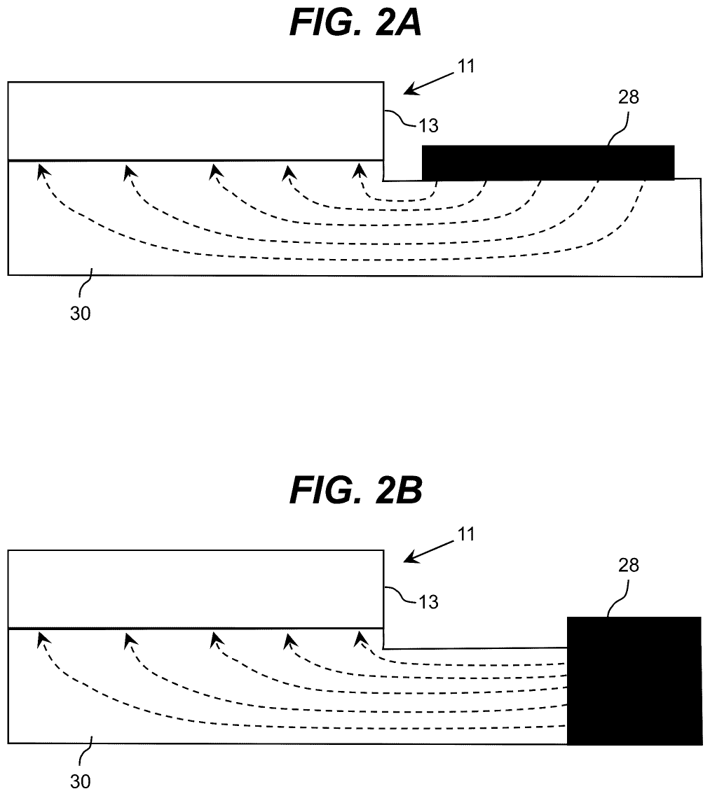

Regardless, the n-type current spreading layer 30 includes one or more attributes configured to increase its conductivity. To this extent, FIGS. 2A and 2B show illustrative current flow through a current spreading layer 30 during operation of a corresponding optoelectronic device according to embodiments. As illustrated in FIG. 2A, during operation, current can flow vertically beneath the n-type contact 28, laterally through the current spreading layer 30 and below the mesa 11, and vertically into the mesa 11. As illustrated in FIG. 2B, an embodiment of the contact 28 can physically contact a side surface of the current spreading layer 30. In this configuration, the current can flow laterally from the contact 28 through the current spreading layer 30 and vertically into the mesa 11.

In prior art optoelectronic devices, the current flow is highest under the mesa 11 on an n-type contact side 13 of the mesa 11 that is located closest to the n-type contact 28. Embodiments of the current spreading layer 30 are configured to distribute the current flow away from the n-type side of the mesa 13 and below the mesa 13, which can result in a more even distribution of vertical current flow throughout the mesa 11.

In embodiments, the n-type current spreading layer 30 includes a level of impurity doping that increases the conductivity without degrading the material quality. In more particular embodiments, the impurity is silicon and/or germanium. In more particular embodiments, a dopant concentration of the impurity doping is in a range between approximately 1×10¹⁷ cm⁻³ and approximately 1×10²¹ cm⁻³. Embodiments of the n-type layer 16, when included, can have a dopant concentration in a range between approximately 5×10¹⁸ cm⁻³ and approximately 5×10¹⁹ cm⁻³.

In embodiments, the n-type current spreading layer 30 can be grown to a thickness that increases the conductivity without degrading the material (e.g., due to film relaxation, cracking, or surface degradation). In more particular embodiments, the thickness is in a range between approximately 0.1 microns and 10 microns.

In embodiments, the n-type current spreading layer 30 includes multiple polarization doped channel layers. Inclusion of such channel layers can provide improved current spreading with a smaller thickness. At a heterojunction of two materials with different degrees of polarization, a sheet charge can be created. This sheet charge can be created in an undoped material, and is confined to a very thin layer. The carriers can exhibit a much higher mobility than carriers in impurity doped materials. If the heterojunction includes a lattice mismatch, a piezoelectric effect may further improve the sheet charge or mobility. Multiple heterojunctions can be stacked to create a highly conductive current spreading layer 30.

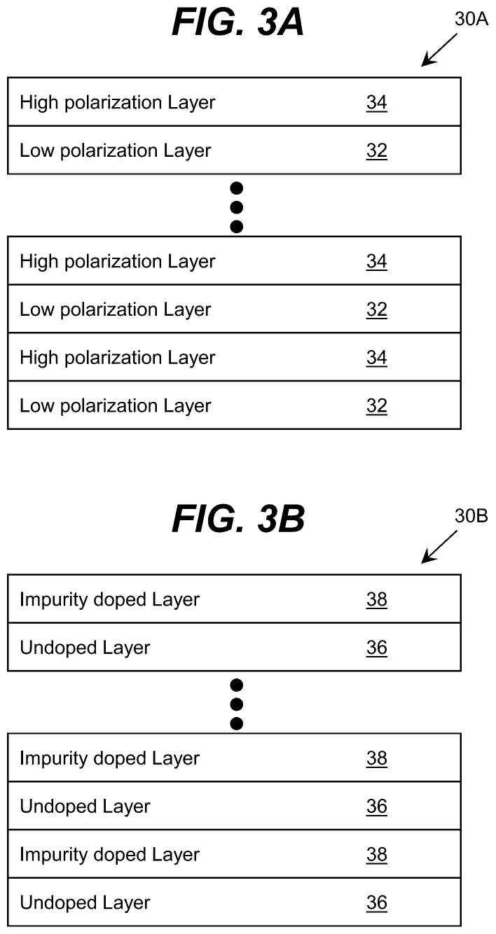

FIGS. 3A and 3B show illustrative n-type current spreading layers 30A, 30B, respectively, according to embodiments. As illustrated in FIG. 3A, the n-type current spreading layer 30A can comprise a plurality of layers including alternating sub-types of layers including low polarization layers 32 and high polarization layers 34. In this case, it is understood that “low polarization” refers to the polarization of the layer 32 as compared to the polarization of the layer 34. Similarly, “high polarization” refers to the polarization of the layer 34 as compared to the polarization of the layer 32. To this extent, no particular range of polarization values is inferred by the corresponding names for the layers 32, 34. In embodiments, the different polarizations are obtained by changing the composition of the layers. In more particular embodiments, the layers 32, 34 are group III nitride layers in which the composition of group III elements are changed to obtain different polarizations. For example, a group III nitride composition with a higher aluminum content will typically have a higher polarization. In embodiments, the group III molar fractions of aluminum in each layer 32, 34 differ by at least ten percent. In more particular embodiments, each layer 32, 34 includes aluminum.

In embodiments, the different polarizations can be created through different doping used in the alternating layers. For example, as shown in FIG. 3B, an embodiment of the n-type current spreading layer 30B can include alternating layers of undoped layers 36 and impurity doped layers 38. The n-type current spreading layer 30B can be configured similar to the n-type current spreading layer 30A shown in FIG. 3A. In this case, the n-type current spreading layer 30B can include much less impurity doping than a typical bulk impurity doped layer, which can improve material quality for the n-type current spreading layer 30B. In more particular embodiments, the impurity is silicon and/or germanium. In more particular embodiments, a dopant concentration of the impurity doping is below approximately 1×10¹⁸ cm⁻³.

In embodiments, a combination of different compositions, such as group III nitride compositions, and different doping levels can be used to create desired different polarizations for the alternating layers.

In embodiments, different approaches described herein are used for different pairs of layers included in the n-type current spreading layer 30.

While a particular number and configuration of layers is shown for each n-type current spreading layer 30A, 30B, it is understood that embodiments of the n-type current spreading layer 30 can include any number of layers and can include either sub-type of layer (e.g., low/high polarization, undoped/impurity doped) as the first layer and either sub-type of layer as the last layer. In embodiments, the n-type current spreading layer 30 can have a first layer and a last layer that are the both the same sub-type of layer.

In embodiments, a thickness of a layer included in an n-type current spreading layer 30 can vary based on a composition of the layer. For example, for group III nitride compositions, a layer having a lower group III molar fraction of aluminum can have a thickness between approximately 50 nanometers and 500 nanometers, whereas a layer having a higher group III molar fraction of aluminum can have a thickness between approximately 5 nanometers and 100 nanometers. In embodiments, a thickness of the layer having the higher group III molar fraction of aluminum is at most half a thickness of the layer having the lower group III molar fraction of aluminum. In general, a higher aluminum content results in a higher polarization for the layer.

In embodiments, an n-type current spreading layer 30 can include a total of approximately 4 to 400 layers of alternating sub-types (e.g., 2 to 200 pairs of layers of different sub-types).

Furthermore, embodiments of the n-type current spreading layer 30 can have a smaller thickness than a comparable bulk impurity doped layer, which can improve material quality and reduce cost. In embodiments, a thickness of the n-type current spreading layer 30 is between approximately 0.1 microns and 1 micron. In embodiments, a thickness of the n-type layer 16, when included, is between approximately 0.1 microns and 3 microns.

While illustrative aspects of the invention have been shown and described herein primarily in conjunction with a heterostructure for an optoelectronic device and a method of fabricating such a heterostructure and/or device, it is understood that aspects of the invention further provide various alternative embodiments.

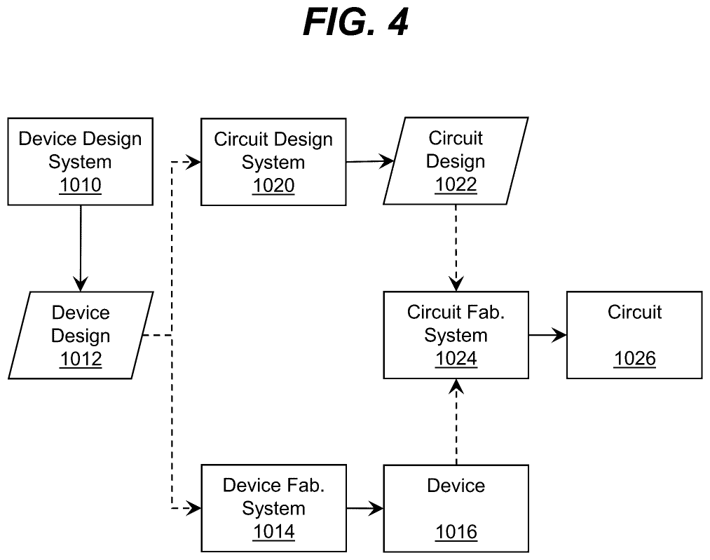

In one embodiment, the invention provides a method of designing and/or fabricating a circuit that includes one or more of the devices designed and fabricated as described herein. To this extent, FIG. 4 shows an illustrative flow diagram for fabricating a circuit 1026 according to an embodiment. Initially, a user can utilize a device design system 1010 to generate a device design 1012 for a semiconductor device as described herein. The device design 1012 can comprise program code, which can be used by a device fabrication system 1014 to generate a set of physical devices 1016 according to the features defined by the device design 1012. Similarly, the device design 1012 can be provided to a circuit design system 1020 (e.g., as an available component for use in circuits), which a user can utilize to generate a circuit design 1022 (e.g., by connecting one or more inputs and outputs to various devices included in a circuit). The circuit design 1022 can comprise program code that includes a device designed as described herein. In any event, the circuit design 1022 and/or one or more physical devices 1016 can be provided to a circuit fabrication system 1024, which can generate a physical circuit 1026 according to the circuit design 1022. The physical circuit 1026 can include one or more devices 1016 designed as described herein.

In another embodiment, the invention provides a device design system 1010 for designing and/or a device fabrication system 1014 for fabricating a semiconductor device 1016 as described herein. In this case, the system 1010, 1014 can comprise a general purpose computing device, which is programmed to implement a method of designing and/or fabricating the semiconductor device 1016 as described herein. Similarly, an embodiment of the invention provides a circuit design system 1020 for designing and/or a circuit fabrication system 1024 for fabricating a circuit 1026 that includes at least one device 1016 designed and/or fabricated as described herein. In this case, the system 1020, 1024 can comprise a general purpose computing device, which is programmed to implement a method of designing and/or fabricating the circuit 1026 including at least one semiconductor device 116 as described herein.

In still another embodiment, the invention provides a computer program fixed in at least one computer-readable medium, which when executed, enables a computer system to implement a method of designing and/or fabricating a semiconductor device as described herein. For example, the computer program can enable the device design system 1010 to generate the device design 1012 as described herein. To this extent, the computer-readable medium includes program code, which implements some or all of a process described herein when executed by the computer system. It is understood that the term “computer-readable medium” comprises one or more of any type of tangible medium of expression, now known or later developed, from which a stored copy of the program code can be perceived, reproduced, or otherwise communicated by a computing device.

As used herein, unless otherwise noted, the term “set” means one or more (i.e., at least one) and the phrase “any solution” means any now known or later developed solution. The singular forms “a,” “an,” and “the” include the plural forms as well, unless the context clearly indicates otherwise. Additionally, the terms “comprises,” “includes,” “has,” and related forms of each, when used in this specification, specify the presence of stated features, but do not preclude the presence or addition of one or more other features and/or groups thereof.

As also used herein, a layer is a transparent layer when the layer allows at least ten percent of radiation having a target wavelength, which is radiated at a normal incidence to an interface of the layer, to pass there through. Furthermore, as used herein, a layer is a reflective layer when the layer reflects at least ten percent of radiation having a target wavelength, which is radiated at a normal incidence to an interface of the layer. In an embodiment, the target wavelength of the radiation corresponds to a wavelength of radiation emitted or sensed (e.g., peak wavelength+/−five nanometers) by an active region of an optoelectronic device during operation of the device. For a given layer, the wavelength can be measured in a material of consideration and can depend on a refractive index of the material. Additionally, as used herein, a contact is considered “ohmic” when the contact exhibits close to linear current-voltage behavior over a relevant range of currents/voltages to enable use of a linear dependence to approximate the current-voltage relation through the contact region within the relevant range of currents/voltages to a desired accuracy (e.g., +/−one percent).

It is understood that, unless otherwise specified, each value is approximate and each range of values included herein is inclusive of the end values defining the range. Terms of degree such as “generally,” “substantially,” “about,” and “approximately” as used herein mean a reasonable amount of deviation of the modified term such that the end result is not significantly changed. For example, these terms can be construed as including a deviation of at least +/−0.5% of the modified term if this deviation would not negate the meaning of the word it modifies. In a more particular example, the term “approximately” is inclusive of values within +/−ten percent of the stated value, while the term “substantially” is inclusive of values within +/−five percent of the stated value when these deviations would not negate the meaning of the word each term modifies. Unless otherwise stated, two values are “similar” when the amount of deviation between the two values does not significantly change the result. In a more particular example, two values are similar when the smaller value is within +/−twenty-five percent of the larger value. A value, y, is on the order of a stated value, x, when the value y satisfies the formula 0.1x≤y≤10x.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. An optoelectronic device comprising:
a first semiconductor layer having a first conductivity type;
a mesa located on a first portion of a surface of the first semiconductor layer, the mesa including:
an active region located on the first semiconductor layer, wherein the active regions is configured to emit or sense radiation having a peak wavelength during operation of the optoelectronic device; and
a second semiconductor layer having a second conductivity type located on the active region; and
a contact located adjacent to the first semiconductor layer on a first side of the mesa, wherein the first semiconductor layer is configured to distribute current flow away from the first side of the mesa during operation of the optoelectronic device.

2. The device of claim 1, wherein the first semiconductor layer includes an impurity dopant concentration in a range between approximately 1×10¹⁷ cm⁻³ and approximately 1×10²¹ cm⁻³.

3. The device of claim 1, wherein the first semiconductor layer includes a plurality of polarization doped channel layers.

4. The device of claim 3, wherein each of the plurality of polarization doped channel layers comprises a sheet charge formed at a heterojunction between a first sub-layer and a second sub-layer of a pair of sub-layers of the first semiconductor layer.

5. The device of claim 4, wherein, for at least one of the plurality of polarization doped channel layers, one of the first sub-layer or the second sub-layer of the pair of sub-layers is undoped and the other of the first sub-layer or the second sub-layer is impurity doped.

6. The device of claim 4, wherein, for at least one of the plurality of polarization doped channel layers, the heterojunction includes a lattice mismatch.

7. The device of claim 4, wherein the pair of sub-layers comprise group III nitride materials, and wherein the second sub-layer has a higher aluminum content than an aluminum content of the first sub-layer.

8. The device of claim 7, wherein the first sub-layer has a larger thickness than a thickness of the second sub-layer.

9. The device of claim 3, wherein the first semiconductor layer includes between 2 and 200 polarization doped channel layers.

10. The device of claim 1, further comprising a third semiconductor layer having the first conductivity type, wherein the first semiconductor layer is located between the second and third semiconductor layers.

11. The device of claim 1, wherein the first conductivity type is n-type and the second conductivity type is p-type.

12. The device of claim 1, wherein the contact is located on a second portion of the surface of the first semiconductor layer adjacent to the mesa.

13. The device of claim 1, wherein the peak wavelength of the radiation is within an ultraviolet range of wavelengths.

14. The device of claim 1, wherein the peak wavelength of the radiation is within a range of wavelengths between approximately 210 and approximately 360 nanometers.

15. An optoelectronic device comprising:
a first semiconductor layer having an n-type conductivity;
a mesa located on a first portion of a surface of the first semiconductor layer, the mesa including:
an active region located on the first semiconductor layer, wherein the active region is configured to emit ultraviolet radiation during operation of the optoelectronic device; and
a second semiconductor layer having a p-type conductivity located on the active region; and
an n-type contact located adjacent to the first semiconductor layer on a first side of the mesa, wherein the first semiconductor layer includes a plurality of polarization doped channel layers.

16. The device of claim 15, wherein each of the plurality of polarization doped channel layers comprises a sheet charge formed at a heterojunction between a first sub-layer and a second sub-layer of a pair of sub-layers of the first semiconductor layer.

17. The device of claim 16, wherein, for at least one of the plurality of polarization doped channel layers, one of the first sub-layer or the second sub-layer of the pair of sub-layers is undoped and the other of the first sub-layer or the second sub-layer is impurity doped.

18. The device of claim 16, wherein, for at least one of the plurality of polarization doped channel layers, the heterojunction includes a lattice mismatch.

19. The device of claim 16, wherein the pair of sub-layers comprise group III nitride materials, and wherein the second sub-layer has a higher aluminum content than an aluminum content of the first sub-layer.

20. An optoelectronic device comprising:
a group III-nitride based heterostructure including:
a first semiconductor layer having an n-type conductivity; and
a mesa located on a first portion of a surface of the first semiconductor layer, the mesa including:
an active region located on the first semiconductor layer, wherein the active region is configured to emit ultraviolet radiation during operation of the optoelectronic device; and
a second semiconductor layer having a p-type conductivity located on the active region; and
an n-type contact located on a second portion of the surface of the first semiconductor layer adjacent to the mesa, wherein the first semiconductor layer includes a plurality of polarization doped channel layers.
